(19) United States
(12) Patent Application Publication
(10) Pub. No.: US 2026/0006751 A1
(43) Pub. Date: Jan. 1, 2026

(54) COOLING SYSTEMS AND METHODS OF OPERATING THE SAME

(71) Applicant: Taiwan Semiconductor Manufacturing Company, Ltd., Hsinchu (TW)

(72) Inventors: Chung-Chiu WU, Hsinchu (TW); Wei-Sheng LIN, Hsinchu (TW)

(73) Assignee: Taiwan Semiconductor Manufacturing Company, Ltd., Hsinchu (TW)

(21) Appl. No.: 18/759,612

(22) Filed: Jun. 28, 2024

(51) Int. Cl. H05K 7/20

(52) U.S. Cl. CPC H05K 7/20381; H05K 7/20318; H05K 7/20327; H05K 7/208

(57) ABSTRACT

An embodiment two-phase cooling system includes an enclosure having a first volume and a second volume, a heat source located in the first volume, and a liquid coolant located in the first volume such that the liquid coolant is in contact with the heat source. A vapor partially filling the second volume is generated by the liquid coolant when heat generated by the heat source is absorbed by the liquid coolant. A condenser located in the second volume removes heat from the vapor, thereby condensing the vapor into condensed liquid coolant that returns to the first volume. A space-filling device, located in the second volume, partially fills the second volume, and thereby displaces the vapor from a portion of the second volume. The space-filling device increases a height of the vapor such that an overlap between the vapor and the condenser is increased, thereby increasing a condenser efficiency.

### BACKGROUND

Cooling systems are used to maintain optimal temperatures in computer systems, especially for components such as central processing units (CPUs) and graphics processing units (GPUs) that generate considerable heat during operation. There are several types of cooling solutions, including air cooling, liquid cooling, and phase-change cooling. Each has its own advantages and is suited for different scenarios depending on factors including performance requirements, space constraints, and budget. Liquid cooling systems are increasingly being adopted in high-performance computing environments where conventional air cooling may fall short in dissipating the heat generated by components such as CPUs and GPUs.

One key advantage of liquid cooling lies in its efficiency at transferring heat away from heat sources. In contrast to air, liquid has a higher heat capacity, enabling it to absorb more heat before reaching critical temperatures. Additionally, liquid cooling solutions tend to operate more quietly than their air-cooled counterparts, as they rely on pumps rather than fans for heat dissipation. This reduced noise level can be particularly appealing in environments where noise is a concern. Despite advances in liquid cooling systems, challenges remain and there is an ongoing need for improvement in cooling systems for computer components and data systems.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a two-phase cooling system, according to a comparative embodiment.

FIG. 1B is a top view of the two-phase cooling system of FIG. 1A illustrating one configuration of a condenser.

FIG. 1C is a top view of the two-phase cooling system of FIG. 1A illustrating a further configuration of a condenser, according to a comparative embodiment.

FIG. 2A is a three-dimensional perspective view of a two-phase cooling system 200 in a first configuration, according to various embodiments.

FIG. 2B is a three-dimensional perspective view of the two-phase cooling system 200 in a second configuration, according to various embodiments.

FIG. 3A is a vertical cross-sectional view of a two-phase cooling system in a first configuration, according to various embodiments.

FIG. 3B is a vertical cross-sectional view of the two-phase cooling system of FIG. 3A in a further configuration, according to various embodiments.

FIG. 3C is a vertical cross-sectional view of the two-phase cooling system of FIG. 3A in a further configuration, according to various embodiments.

FIG. 4A is a vertical cross-sectional view of a two-phase cooling system in a first configuration, according to various embodiments.

FIG. 4B is a vertical cross-sectional view of the two-phase cooling system of FIG. 4A in a further configuration, according to various embodiments.

FIG. 5A is a vertical cross-sectional view of a two-phase cooling system in a first configuration, according to various embodiments.

FIG. 5B is a vertical cross-sectional view of the two-phase cooling system of FIG. 5A in a further configuration, according to various embodiments.

FIG. 5C is a vertical cross-sectional view of the two-phase cooling system of FIG. 5A in a further configuration, according to various embodiments.

FIG. 6A is a vertical cross-sectional view of a two-phase cooling system in a first configuration, according to various embodiments.

FIG. 6B is a vertical cross-sectional view of the two-phase cooling system of FIG. 6A in a further configuration, according to various embodiments.

FIG. 6C is a vertical cross-sectional view of the two-phase cooling system of FIG. 6A in a further configuration, according to various embodiments.

FIG. 7A is a vertical cross-sectional view of a two-phase cooling system in a first configuration, according to various embodiments.

FIG. 7B is a vertical cross-sectional view of the two-phase cooling system of FIG. 7A in a further configuration, according to various embodiments.

FIG. 7C is a vertical cross-sectional view of the two-phase cooling system of FIG. 7A in a further configuration, according to various embodiments.

FIG. 8A is a vertical cross-sectional view of a two-phase cooling system, according to various embodiments.

FIG. 8B is a three-dimensional perspective view of the two-phase cooling system of FIG. 8A, according to various embodiments.

FIG. 9 is a flowchart illustrating operations of a method of cooling a computing device, according to various embodiments.

FIG. 10 is a flowchart illustrating operations of a method of cooling a computing device, according to various embodiments.

### DETAILED DESCRIPTION

The following disclosure provides many different embodiments, or examples, for implementing various features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Disclosed embodiments provide cooling systems for computer system components having advantages over related cooling systems. In this regard, two-phase cooling systems are provided that include a liquid coolant (i.e., a first phase) that absorbs heat from the computer system components and thereby generates a vapor (i.e., a second phase) that is cooled by a condenser to remove the heat. A vapor control device is provided, which alters a density distribution of the vapor to increase a spatial overlap of the vapor with the condenser, to thereby increase an efficiency of the heat-transfer coupling between the vapor and the condenser. In various embodiments, the vapor control device takes the form of a space-filling device, a deformable object, an inflatable bag, a fan, and an expandable container. Each of the embodiment vapor control devices displaces the vapor toward the condenser, thereby improving heat transfer between the vapor and the condenser, leading to a corresponding improvement in overall cooling system performance.

Liquid cooling is increasingly being adopted in computer servers, particularly in data centers and high-performance computing (HPC) environments. While air cooling has traditionally been the dominant method for cooling servers due to its simplicity and lower initial costs, liquid cooling offers several advantages that make it appealing for certain server deployments. In data centers, where energy efficiency and cooling capacity are important concerns, liquid cooling may offer significant benefits. Liquid cooling systems may more effectively remove heat from server components, enabling higher-density deployments without risking overheating. This allows data center operators to maximize their server density within the same footprint, reducing the overall space requirements and potentially lowering operational costs.

Liquid cooling also enables more efficient cooling of high-power components, such as CPUs, GPUs, and memory modules, which are increasingly common in modern server architectures. By keeping these components at optimal operating temperatures, liquid cooling may improve performance and reliability, leading to better overall server efficiency. Moreover, liquid cooling may contribute to energy savings in data centers by reducing the need for mechanical cooling systems, such as air conditioning units. By leveraging liquid cooling solutions that utilize ambient or recycled water, data centers may achieve significant reductions in power consumption and cooling costs.

Adoption of liquid cooling in server environments is growing but is not yet ubiquitous. Challenges such as upfront costs, system complexity, maintenance requirements, and concerns about potential leaks or system failures may still limit widespread adoption liquid cooling systems. However, as the demand for higher computing densities, energy efficiency, and performance continues to rise, liquid cooling is likely to become increasingly prevalent in server deployments, especially in specialized HPC and hyperscale data center environments.

Liquid cooling technology includes phase-change cooling and two-phase cooling systems. Phase-change cooling and two-phase cooling share the fundamental principle of utilizing phase transitions to achieve cooling, but they differ in their implementation and operation. Phase-change cooling systems employ a refrigerant that undergoes a phase change from liquid to gas and back again to efficiently transfer heat away from heat generating components. This process involves a closed-loop system that includes a compressor, condenser, expansion valve, and evaporator. The compressor compresses the refrigerant into a high-pressure liquid, which then passes through the condenser to release heat and to condense the refrigerant into a liquid. After passing through an expansion valve, the refrigerant evaporates into a low-pressure gas, absorbing heat from the component that is being cooled. This gas is then cycled back to the compressor to repeat the process.

In contrast, two-phase cooling encompasses a broader category of cooling techniques where both liquid and vapor phases of the coolant coexist simultaneously. In these systems, the coolant partially vaporizes as it absorbs heat from the component, and the resulting mixture of liquid and vapor interacts with a heat exchanger (i.e., a condenser) where the vapor condenses back into liquid, releasing the absorbed heat. This condensed liquid then returns to the component to continue the cooling cycle. Thus, while phase-change cooling is a specific type of cooling system involving phase changes between liquid and gas states, two-phase cooling encompasses a wider range of techniques utilizing both liquid and vapor phases of the coolant concurrently.

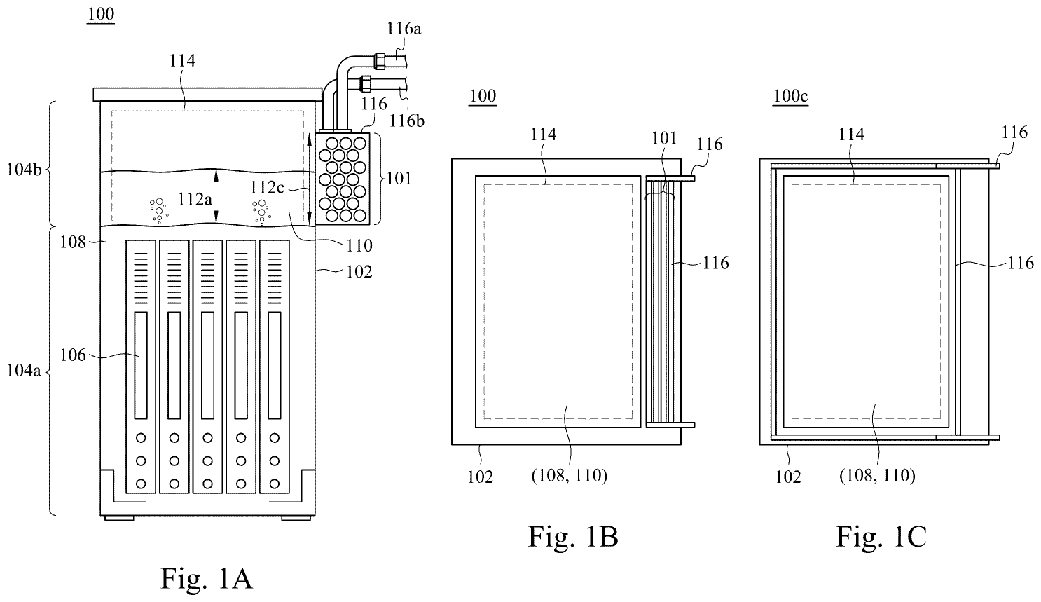

FIG. 1A is a vertical cross-sectional view of a two-phase cooling system 100, according to a comparative embodiment. FIG. 1B is a top view of the two-phase cooling system 100 of FIG. 1A illustrating one configuration of a condenser 101, and FIG. 1C is a top view of the two-phase cooling system of FIG. 1A illustrating a further configuration of a condenser 101, according to a further comparative embodiment. As shown in FIG. 1A, the two-phase cooling system 100 includes an enclosure 102 having a first volume 104a and a second volume 104b. The two-phase cooling system 100 includes a heat source 106 located in the first volume 104a and a liquid coolant 108 located in the first volume 104a such that the liquid coolant 108 is in contact with the heat source 106. As described above, the two-phase cooling system 100 may be part of a computing system, computer server, data center, etc. As such, in some embodiments, a computing device that generates heat functions as the heat source 106.

As the system is operated, heat generated by the heat source 106 is absorbed by the liquid coolant 108, which generates a vapor 110. As shown in FIG. 1A, the vapor 110 partially fills the second volume 104b. If the system were in thermodynamic equilibrium one might expect that the vapor 110 would uniformly fill the second volume 104b. However, during operation, the two-phase cooling system 100 is not in thermodynamic equilibrium, but rather, is in a non-equilibrium steady state in which the vapor 110 is continually generated by heat absorbed by the liquid coolant 108 from the heat source 106. In turn, the vapor 110 generated by the liquid coolant 108 is continually being condensed back into condensed liquid coolant by the condenser 101, which returns to the first volume 104a. In this way, heat is transferred from the heat source 106, the liquid coolant 108, to the vapor 110, to the condenser 101, and finally out of the system.

Due to the non-equilibrium operation of the two-phase cooling system 100, the vapor 110 does not uniformly fill the second volume 104b. Rather, the vapor 110 has a density distribution characterized by a first height 112a. For example, the vapor 110 has a density distribution that decreases with distance above a surface of the liquid coolant 108 with a characteristic length scale corresponding to the first height 112a. In this regard, in some embodiments, the vapor density distribution has an exponentially decreasing density as a function of distance above the surface of the liquid coolant 108, with the first height 112a identified as a characteristic length scale of the exponential density dependence. In general, the second volume 104b includes a mixture of vapor 110 and air. The vapor 110 will tend to reside in the bottom of the second volume 104b because it has a greater density (e.g. −0.012 g/ml) than that of air (0.0013 g/ml).

As shown in FIGS. 1A and 1B, the condenser 101 is located adjacent to a central region 114 of the second volume 104b such that the vapor 110 comes in contact with the condenser 101. The condenser includes a conduit 116 through which a condenser coolant (not shown) flows, such that the condenser coolant absorbs heat from a portion of the vapor 110 that comes in contact with the conduit 116. As shown in FIG. 1A, the conduit 116 includes an inlet conduit 116a and an outlet conduit 116b that allows condenser coolant to flow into and out from the condenser 101. Various materials may be used for the condenser coolant, such as water, a refrigerant, etc.

The degree to which the vapor 110 interacts with the condenser 101 depends on the first height 112a of the vapor. As described above, the first height 112a depends on the non-equilibrium state of the vapor 110. As such, the first height 112a is a function of a rate at which heat is generated by the heat source 106 and a rate at which heat is removed from the vapor 110 by the condenser 101. The heat generation and removal rates further depend on the temperature difference between the heat source 106 and the condenser 101 as well as on the coupling efficiency between the condenser 101 and the vapor 110. As shown in FIG. 1A, the vapor 110 does not fully overlap with the condenser 101 due to the fact that the vapor 110 does not fully fill the second volume 104b.

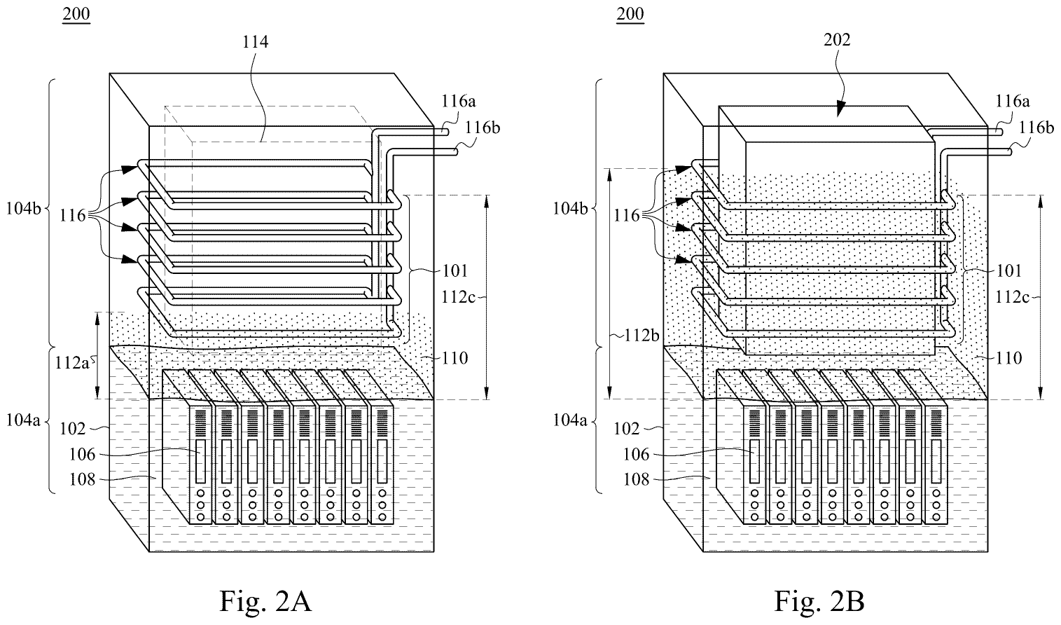

According to various embodiments, described below, a vapor control device is used to increase a height of the vapor 110 to a second height 112b which is greater than the first height 112a, thus increasing a coupling efficiency between the vapor 110 and the condenser 101. In this regard, in some embodiments, the condenser conduit 116 is formed as a coil (e.g., see FIGS. 1B and 1C) extending vertically to a third height 112c above a surface of the liquid coolant 108 (e.g., see FIGS. 1A, 2A, and 2B).

As shown in FIGS. 1B and 1C, the condenser 101 is configured to leave the central region 114 of the second volume 104b free of any components of the condenser 101. Leaving such a central region 114 free may be advantageous by providing a space that may be accessed during installation and maintenance of the computer system components that are housed in the first volume 104a. For example, as shown in FIG. 1B, the condenser 101 is located in a space that is adjacent to the central region 114. Alternatively, as shown in FIG. 1C, the condenser 101 is formed as a coil around a perimeter of the central region 114. Although the central region 114 provides a convenient access volume for maintenance operations, its presence represents a disadvantage in terms of coupling efficiency between the condenser 101 and the vapor 110. In this regard, the central region 114 represents a volume in which there is no spatial overlap between the vapor 110 and the condenser 101, and as such, there is no coupling between the condenser 101 and the vapor 110 in the central region 114. However, the central region 114 provides a space to accommodate a vapor control device taking the form of a space-filling device 202, which is used to displace the vapor 110 toward the condenser 101, as described in greater detail below,

FIG. 2A is a schematic view of a two-phase cooling system 200 in a first configuration, where a second volume 104b is shown in a three-dimensional perspective view, and FIG. 2B is schematic view of the two-phase cooling system 200 of FIG. 2A in a second configuration, according to various embodiments. As shown in FIGS. 2A and 2B, the two-phase cooling system 200 includes an enclosure 102 having a first volume 104a and a second volume 104b, a heat source 106 located in the first volume 104a, and a liquid coolant 108 located in the first volume 104a such that the liquid coolant 108 is in contact with the heat source 106. A vapor 110 that partially fills the second volume 104b is generated by the liquid coolant 108 when heat generated by the heat source 106 is absorbed by the liquid coolant 108. As shown in FIGS. 2A and 2B, a condenser 101 is located in the second volume 104b and is configured to remove heat from the vapor 110. By removing heat from the vapor 110, the condenser 101 causes the vapor 110 to condense into condensed liquid coolant that returns to the first volume 104a.

In contrast to the two-phase cooling system 100 of FIGS. 1A to 1C, the two-phase cooling system 200 further includes a space-filling device 202 located in the second volume 104b, as shown in FIG. 2B. The space-filling device 202 partially fills the second volume 104b and thereby displaces the vapor 110 from a portion of the second volume 104b. The displaced vapor 110 fills areas surrounding the space-filling device 202 and, as such, a height of the vapor 110 is increased from the first height 112a, which characterizes the vapor 110 when the space-filling device 202 is removed from the second volume 104b, to the second height 112b, which characterizes the vapor 110 when the space-filling device 202 is placed within the second volume 104b.

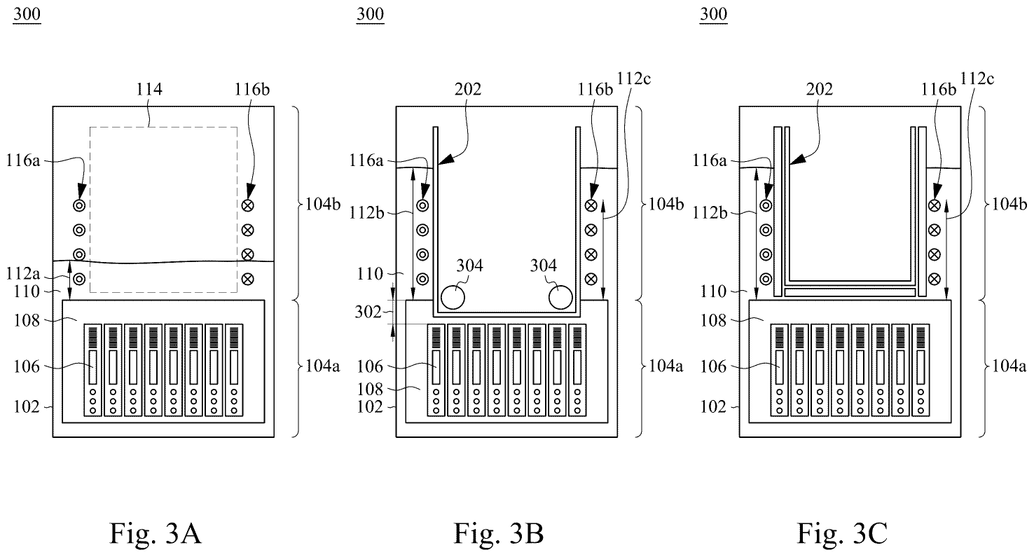

As shown in FIGS. 2A and 2B, the space-filling device 202 is configured as a removable object that is located in the central region 114 of the second volume 104b during operation of the two-phase cooling system 200, as shown in FIG. 2B. Alternatively, the space-filling device 202 may be removed from the two-phase cooling system 200, thereby leaving the central region 114 free, during installation and maintenance operations. Various space-filling devices 202 are described in greater detail with reference to FIGS. 3A to 6C, below, in corresponding embodiments.

The first height 112a of the vapor 110 above a surface of the liquid coolant is a function of the temperature of the liquid coolant 108, the temperature of the condenser 101, and the specific properties of the liquid coolant 108. In certain embodiments, the liquid coolant 108 is a fluorine-based chemical having a boiling point between 46° C. and 55° C., a latent heat between 90 KJ/kg and 125 KJ/kg, and a vapor pressure between 30 kPa and 40 kPa at temperature of approximately 20° C. Some example chemicals that may be used as the liquid coolant 108 are listed as follows: HT-55 ((perfluoropolyether) (1-propene, 1,1,2,3,3,3-hexafluoro-, oxidized, polymerized)) available from Galden; Novec 7200 (ethyl nonafluoroisobutyl ether) available from 3M; FC16P (1,1,1,2,2,4,5,5,5-nonafluoro-4-(trifluoromethyl)-3-pentanone) available from Taimax; Novec 649 (1,1,1,2,2,4,5,5,5-nonafluoro-4-(trifluoromethyl)-3-pentanone) available from 3M; FC-3284 (perfluoro compounds, C5-18) available from 3M; FC18P (2-pentene, 1,1,1,2,3,4,5,5,5-nonafluoro-4-(trifluoromethyl)) available from Taimax; IM6 (perfluoro (4-methylpent-2-ene)) available from Inventec; 2100A (perfluoro (4-methylpent-2-ene)) available from Noah; DAISAVE SS-54 (1,1,2,3,3,3-hexafluoropropyl methyl ether) available from Daikin; and Opteon 2P50 (hydrofluoroolefin) available from Chemours.

As described with reference to FIGS. 1B and 1C, above, the condenser 101 includes a conduit 116 through which a condenser coolant (not shown) flows such that the condenser coolant absorbs heat from a portion of the vapor 110 that comes in contact with the conduit 116. Various condenser coolants may be used, such as water, a refrigerant, etc., as long as the condenser coolant is held at a temperature that is lower than the boiling point of the liquid coolant 108.

According to various embodiments, the condenser 101 is located in a region of the second volume 104b that is adjacent to the space-filling device 202 along at least one edge of the space-filling device 202 such that the space-filling device 202 displaces the vapor 110 toward the condenser 101. For example, as shown in FIGS. 1C, 2A, and 2B, the condenser 101 is configured to include a conduit 116 that is formed as a coil around a perimeter of the central region 114 of the second volume 104b. In such a configuration, the conduit 116 is adjacent to outer edges of the space-filling device 202 when the space-filling device 202 is placed within the second volume 104b, as shown in FIG. 2B. Alternatively, as shown in FIGS. 1A and 1B, the condenser 101 includes a conduit 116 configured as a coil located adjacent to a single side of the space-filling device 202. The condenser 101 is configured in various other ways (e.g., adjacent to two sides, three sides, etc., of the space-filling device 202) in other embodiments.

As shown in FIGS. 1A, 2A, and 2B, the condenser 101 spatially extends in a vertical direction characterized by a third height 112c. In this regard, the conduit 116 is formed as a coil extending vertically to a third height 112c above a surface of the liquid coolant 108. As further shown in FIGS. 1A, 2A, and 2B, the third height 112c is greater than the first height 112a such that when the space-filling device 202 is placed within the second volume 104b the vapor 110 is displaced, thereby increasing a degree to which the vapor 110 comes in contact with the condenser 101. For example, as shown in FIG. 2B, the vapor 110 is displaced such that a height of the vapor 110 rises from the first height 112a, as shown in FIG. 2A, to the second height 112b, as shown in FIG. 2B. In this example embodiment, the third height 112c, which characterizes a vertical spatial extent of the condenser 101 is greater than the first height 112a. As such, in the presence of the space-filling device 202, the height increase of the vapor 110 from the first height 112a to the second height 112b allows the vapor 110 to come in contact with the condenser 101 to a greater extent, thus increasing the volume of vapor 110 that is cooled by the condenser 101. As such, the presence of the space-filling device 202 increases the cooling efficiency between the vapor 110 and the condenser 101.

FIG. 3A is a vertical cross-sectional view of a two-phase cooling system 300 in a first configuration, and FIGS. 3B and 3C are vertical cross-sectional views of the two-phase cooling system 300 of FIG. 3A in further respective configurations, according to various embodiments. The two-phase cooling system 300 of FIGS. 3A to 3C is similar to the two-phase cooling system 200 of FIGS. 2A and 2B. The condenser 101 of FIGS. 3A to 3C is similar to the condenser 101 of FIGS. 2A and 2B in that is includes a conduit (116a, 116b) formed as a coil surrounding a central region 114. The cross-sectional view of FIGS. 3A to 3C illustrates first segments 116a and second segments 116b of the conduit (116a, 116b) showing corresponding directions of circulation of a condenser coolant. For example, in the first segments 116a the condenser coolant moves in a direction out of the plane of FIGS. 3A to 3C and in the second segments 116b the condenser coolant moves in a direction into the plane of FIGS. 3A to 3C, as shown.

In each of the configurations of FIGS. 3B and 3C, the two-phase cooling system 300 includes a space-filling device 202 that displaces the vapor 110 to thereby increase a height of the vapor 110 from the first height 112a, as shown in FIG. 3A, to the second height 112b, as shown in FIGS. 3B and 3C. In the embodiment of FIG. 3B, the space-filling device 202 takes the form of an object that floats on a surface of the liquid coolant 108. As shown, the space-filling device 202 of FIG. 3B is an open container. In this regard, the space-filling device 202 floats on the surface of the liquid coolant 108 and displaces the surface of the liquid coolant 108 to a certain depth 302. In certain embodiments, it may be advantageous to further provide one or more weighted objects 304 within the space-filling device 202 to thereby increase the depth 302 to which the space-filling device 202 displaces the surface of the liquid coolant 108. In other embodiments, the space-filling device 202 is a closed container or a solid object, as long as the solid object is chosen to be less dense than the liquid coolant 108 such that it floats on the liquid coolant 108. For example, in some embodiments, the density of the liquid coolant 108 is approximately 1.6 g/ml, so any solid having a density that is less than 1.6 g/ml will float on a surface of the liquid coolant 108.

In the embodiment of FIG. 3C, the space-filling device 202 takes the form of an object that floats in the vapor 110 above a surface of the liquid coolant 108. For example, the space-filling device 202 is made of a material that is comparable or less dense than the vapor 110 such that the space-filling device 202 floats within the vapor. For example, in certain embodiments, the space-filling device 202 is a synthetic foam material having a density of between 0.4 g/cm² and 0.7 g/cm².

As shown, in some embodiments, the space-filling device 202 is configured as an open container. Alternatively, the space-filling device 202 is configured as a closed container or as a solid object in other embodiments. In each of the embodiments of FIGS. 3B and 3C, the space-filling device 202 displaces the vapor 110 to a second height 112b that is greater than the third height 112c that characterizes a vertical spatial extent of the condenser 101. As such, the presence of the space-filling device 202 modifies the spatial distribution of the vapor 110 from only partially overlapping with the condenser 101 to completely overlapping with the condenser 101, leading to a corresponding increase in the coupling efficiency between the condenser 101 and vapor 110.

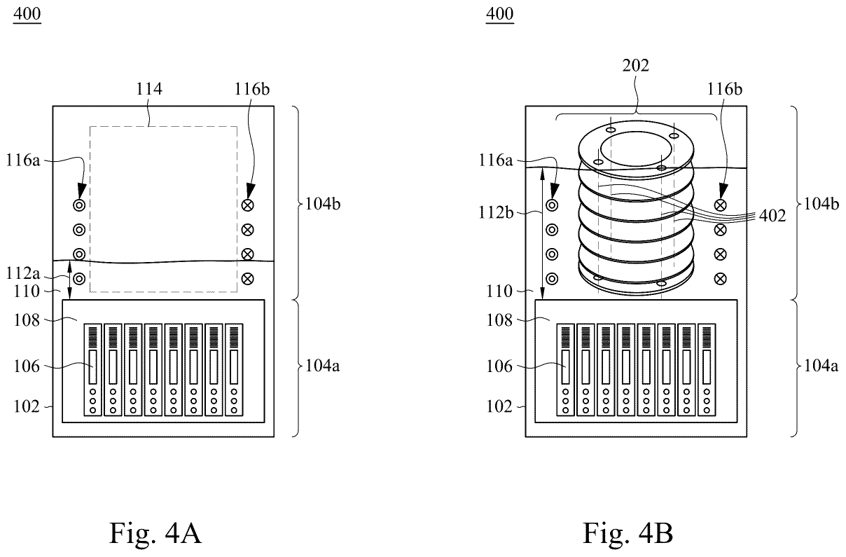

FIG. 4A is a vertical cross-sectional view of a two-phase cooling system 400 in a first configuration, and FIG. 4B is a vertical cross-sectional view of the two-phase cooling system 400 of FIG. 4A in a further configuration, according to various embodiments. The two-phase cooling system 400 of FIGS. 4A and 4B is similar to the two-phase cooling system 300 of FIGS. 3A to 3C and the two-phase cooling system 200 of FIGS. 2A and 2B. In contrast to these previously-described two-phase cooling systems (200, 300), the two-phase cooling system 400 of FIGS. 4A and 4B includes a space-filling device 202 that is a deformable object.

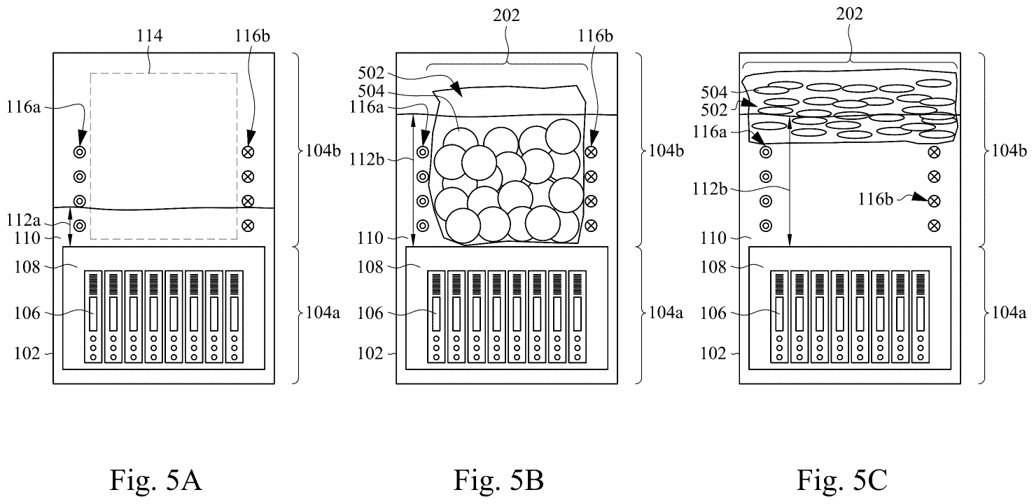

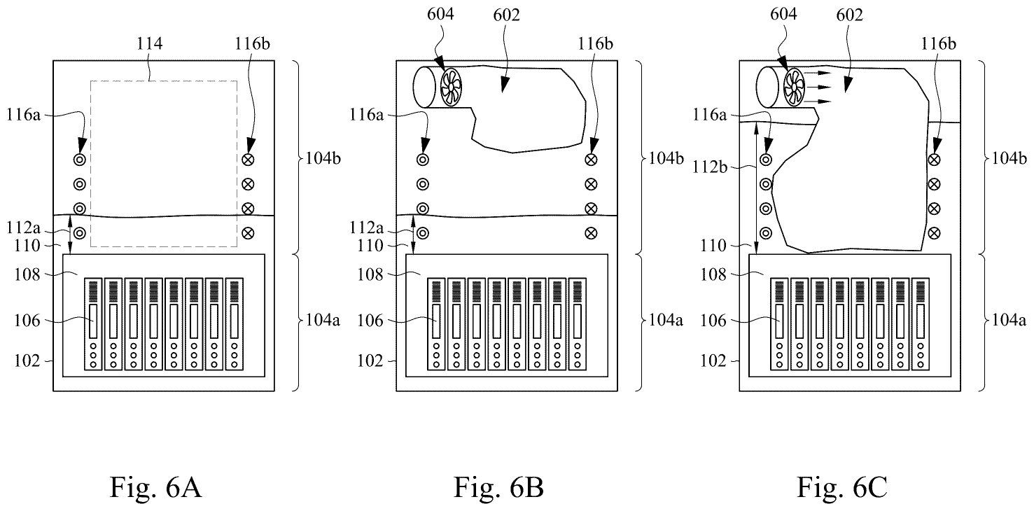

In the example embodiment of FIGS. 4A and 4B, the space-filling device 202 has a reconfigurable volume (only one volume shown is in FIG. 4B) such that in a first configuration the space-filling device 202 has a first size and in a second configuration the space-filling device has a second size that is different from the first size. For example, the space-filling device 202 is a cylindrical bellows having strings 402 that are used to control the size of the bellows in some embodiments. For example, in a fully extended configuration, as shown in FIG. 4B, the bellows has a maximum volume that essentially fills the central region 114. Alternatively, the size of the bellows is reduced (i.e., contracted) by pulling on the strings 402. In other embodiments, various other types of deformable objects may be used as the space-filling device 202, as described in greater detail with reference to FIGS. 5A to 6C, below.

FIG. 5A is a vertical cross-sectional view of a two-phase cooling system 500 in a first configuration, and FIGS. 5B and 5C are vertical cross-sectional views of the two-phase cooling system 500 of FIG. 5A in further respective configurations, according to various embodiments. The two-phase cooling system 500 of FIGS. 5A to 5C is similar to the two-phase cooling system 400 of FIGS. 4A and 4B; the two-phase cooling system 300 of FIGS. 3A to 3C; and the two-phase cooling system 200 of FIGS. 2A and 2B. As with the two-phase cooling system 400 of FIGS. 4A and 4B, the two-phase cooling system 500 includes a space-filling device 202 that is a deformable object.

In this regard, the space-filling device 202 of the two-phase cooling system 500 includes a porous net 502 that holds a plurality of deformable objects 504 within the porous net 502. In an example embodiment, the deformable objects 504 are rubber balls, or similar elastically deformable objects, which are squeezed such that each has a first volume in a first configuration, as shown in FIG. 5B, and each has a second volume (e.g., the smaller squeezed volume) in a second configuration, as shown in FIG. 5C. The volume of the space-filling device 202 is changed by changing a size of the porous net 502. For example, according to some embodiments, the porous net 502 has an adjustable size (e.g., that is controlled by draw strings (not shown)) such that the plurality of deformable objects is compressed by the porous net in the second configuration (e.g., see FIG. 5C) and the plurality of deformable objects are expanded in a first configuration (e.g., see FIG. 5B).

FIG. 6A is a vertical cross-sectional view of a two-phase cooling system 600 in a first configuration, and FIGS. 6B and 6C are vertical cross-sectional views of the two-phase cooling system 600 of FIG. 6A in further respective configurations, according to various embodiments. The two-phase cooling system 600 of FIGS. 6A to 6C is similar to the two-phase cooling system 500 of FIGS. 5A, 5B, and 5C; the two-phase cooling system 400 of FIGS. 4A and 4B; the two-phase cooling system 300 of FIGS. 3A to 3C; and the two-phase cooling system 200 of FIGS. 2A and 2B. As with the two-phase cooling system 500 of FIGS. 5A, 5B, and 5C, the two-phase cooling system 500 includes a space-filling device 202 that is a deformable object.

In this regard, the space-filling device 202 of the two-phase cooling system 500 includes an inflatable bag 602 that has an adjustable size that is increased or decreased by increasing or decreasing a volume of gas within the inflatable bag. As shown in FIGS. 6B and 6C, the two-phase cooling system 600 further includes a fan 604 that is used to add or remove air or other gases to the inflatable bag 602 to thereby increase or decrease the size of the inflatable bag 602.

As shown in FIG. 6B, the inflatable bag 602 has a first size in a first configuration such that inflatable bag does not come in contact with the vapor 110. As such, in the first configuration of FIG. 6B that vapor 110 assumes the first height 112a. In contrast, in a second configuration, as shown in FIG. 6C, the fan 604 is used to add air or other gases to the inflatable bag 602 to thereby increase the size of the inflatable bag 602. As such, the inflatable bag 602 is enlarged so as to come in contact with the vapor 110 and thereby displace the vapor 110. In turn, the vapor 110 is displaced by the inflatable bag 602 such that a height of the vapor 110 is increased to the second height 112b, as shown in FIG. 6C. As in other embodiments described above, the presence of the space-filling device 202 modifies the spatial distribution of the vapor 110 from only partially overlapping with the condenser 101 to completely overlapping with the condenser 101, leading to a corresponding increase in the cooling efficiency between the condenser 101 and vapor 110.

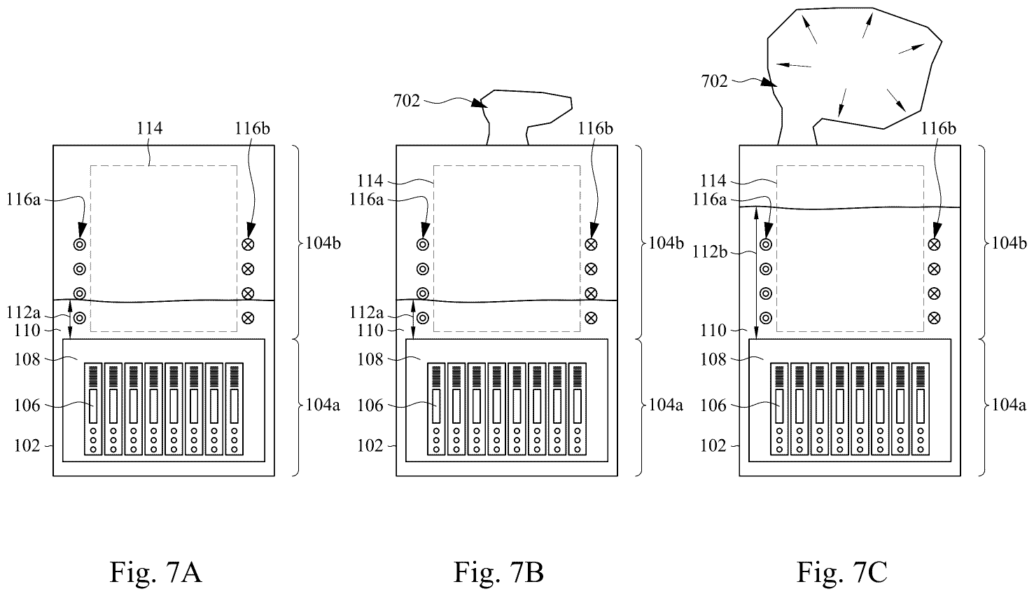

FIG. 7A is a vertical cross-sectional view of a two-phase cooling system 700 in a first configuration, and FIGS. 7B and 7C are vertical cross-sectional views of the two-phase cooling system 700 of FIG. 7A in further respective configurations, according to various embodiments. The two-phase cooling system 700 of FIGS. 7A to 7C is similar to the two-phase cooling system 600 of FIGS. 6A, 6B, and 6C; the two-phase cooling system 500 of FIGS. 5A, 5B, and 5C; the two-phase cooling system 400 of FIGS. 4A and 4B; the two-phase cooling system 300 of FIGS. 3A to 3C; and the two-phase cooling system 200 of FIGS. 2A and 2B. In contrast to these previously-described systems, however, the two-phase cooling system 700 employs a different kind of vapor control device to control a density distribution of the vapor 110.

The vapor control device of FIGS. 7B and 7C is an expandable container 702 such as a ballon or a bellows. The expandable container 702 is attached to an opening of the second volume 104b portion of the enclosure 102 such that air and vapor 110 escape from the second volume 104b into the expandable container 702. A density distribution of the vapor 110 is controlled by allowing gas and vapor 110 to escape from the second volume 104b. For example, in an alternative system (not shown) in which the gas volume is fixed within the second volume 104b, a vapor pressure increases with increasing temperature of the liquid coolant 108. Such a pressure increase constrains the vapor 110 to have the first height 112a, as shown in FIG. 7A. In contrast, by allowing gas and vapor 110 to escape from the second volume 104b, as in the embodiments of FIGS. 7B and 7C, the vapor pressure is maintained. By controlling the pressure in this way, the vapor 110 is not constrained by the presence of the air above the vapor 110. As such, the vapor 110 is allowed to expand within the second volume 104b and, as such, assumes the second height 112b as shown, for example, in FIG. 7C. The increased volume of the vapor 110 then more completely overlaps with the condenser 101, thus increasing the cooling efficiency between the vapor 110 and the condenser 101.

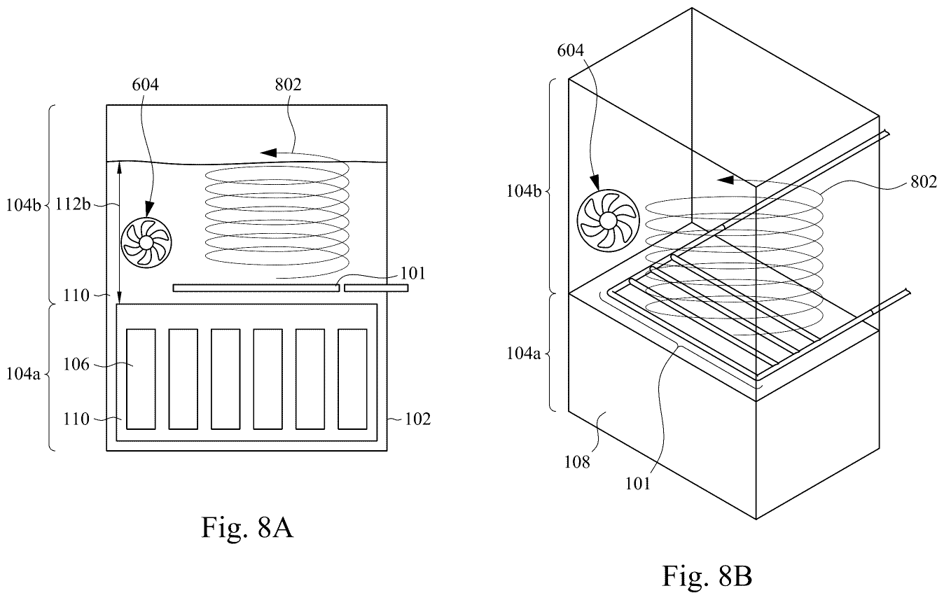

FIG. 8A is a vertical cross-sectional view of a two-phase cooling system 800, and FIG. 8B is a three-dimensional perspective view of the two-phase cooling system 800 of FIG. 8A, according to various embodiments. The two-phase cooling system 800 of FIGS. 8A and 8B is similar to the two-phase cooling system 700 of FIGS. 7A to 7C; the two-phase cooling system 600 of FIGS. 6A, 6B, and 6C; the two-phase cooling system 500 of FIGS. 5A, 5B, and 5C; the two-phase cooling system 400 of FIGS. 4A and 4B; the two-phase cooling system 300 of FIGS. 3A to 3C; and the two-phase cooling system 200 of FIGS. 2A and 2B. In contrast to these previously-described systems, however, the two-phase cooling system 700 employs a different kind of vapor control device to control a density distribution of the vapor 110.

In this regard, a fan 604 is positioned within the second volume 104b of the enclosure or may be positioned externally to the second volume 104b and may be connected to the second volume 104b by a gas conduit (not shown). The fan 604 causes circulation 802 of the vapor 110 and other gases (e.g., air) within the second volume 104b. The circulation 802 of the vapor 110 within the second volume 104b allows a greater amount of the vapor 110 to come into contact with the condenser 101 than would otherwise come into contact with the condenser 101 in the absence of the circulation 802. As such, the fan 604 functions as a vapor control device that increases a cooling efficiency between the vapor 110 and the condenser 101.

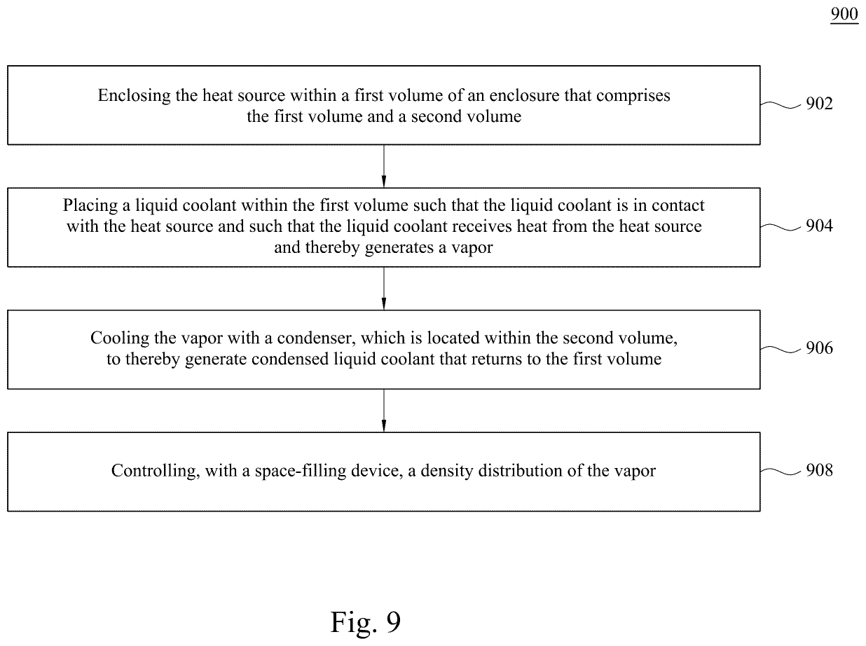

FIG. 9 is a flowchart illustrating operations of a method 900 of cooling a heat source 106, according to various embodiments. In operation 902, the method 900 includes enclosing the heat source 106 within a first volume 104a of an enclosure 102 that includes the first volume 104a and a second volume 104b. In operation 904, the method 900 includes placing a liquid coolant 108 within the first volume 104a such that the liquid coolant 108 is in contact with the heat source 106 and such that the liquid coolant 108 receives heat from the heat source 106 and thereby generates a vapor 110. In operation 906, the method 900 includes cooling the vapor 110 with a condenser 101, which is located within the second volume 104b, to thereby generate condensed liquid coolant 108 that returns to the first volume 104a. In operation 908, the method 900 includes controlling, with a space-filling device 202, a density distribution of the vapor 110.

According to certain embodiments, the space-filling device 202 is a removable object, and the method 900 further includes placing the space-filling device 202 within the second volume 104b such that the space-filling device 202 displaces the vapor 110 thereby causing the vapor 110 to have a second height 112b that is greater than a first height 112a that the vapor 110 has when the space-filling device 202 is removed from the second volume 104b. According to certain embodiments, the removable object is configured to float on the liquid coolant 108 and the method 900 further includes placing the removable object on a surface of the liquid coolant 108 such that the removable object floats on the liquid coolant 108.

According to other embodiments, the space-filling device 202 is a deformable object having a reconfigurable volume, and the method further includes increasing a volume of the space-filling device 202 from a first configuration having a first size to a second configuration having a second size that is larger than the first size such that the deformable object causes the vapor 110 to have a second height 112b that is greater than a first height 112a that the vapor 110 includes when the deformable object has the first size. According to further embodiments, the deformable object is an inflatable bag 602, and the method 900 further includes increasing a volume of gas within the inflatable bag 602 to thereby increase the volume from the first size to the second size.

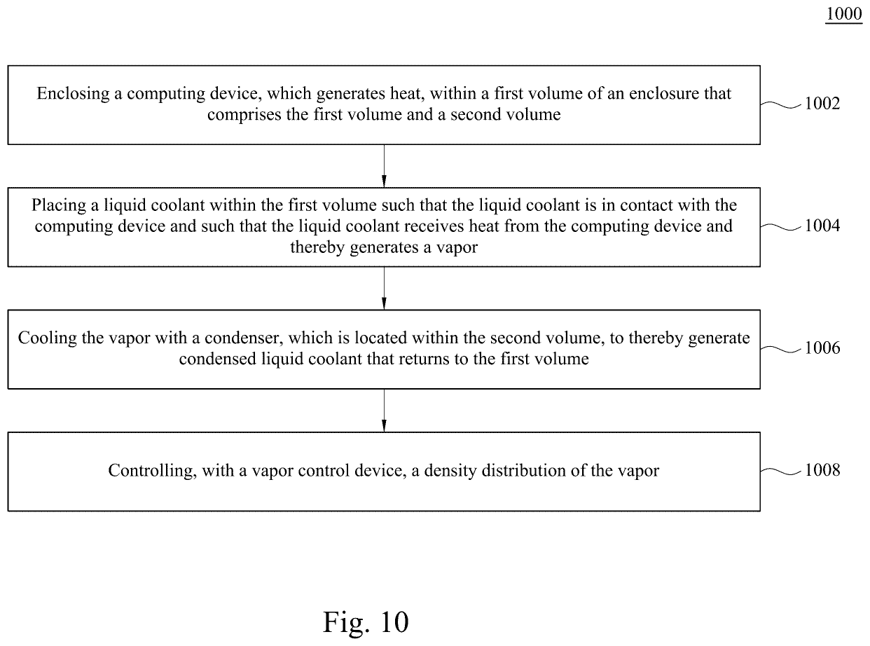

FIG. 10 is a flowchart illustrating operations of a further method 1000 of cooling a computing device 106, according to various embodiments. In operation 1002, the method 1000 includes enclosing a computing device 106, which generates heat, within a first volume 104a of an enclosure 102 that includes the first volume 104a and a second volume 104b. In operation 1004, the method 1000 includes placing a liquid coolant 108 within the first volume 104a such that the liquid coolant 108 is in contact with the computing device 106 and such that the liquid coolant 108 receives heat from the computing device 106 and thereby generates a vapor 110. In operation 1006, the method 1000 includes cooling the vapor 110 with a condenser 101, which is located within the second volume 104b, to thereby generate condensed liquid coolant 108 that returns to the first volume 104a. In operation 1008, the method 1000 includes controlling, with a vapor control device (202, 602, 604, 702), a density distribution of the vapor 110.

In certain embodiments, an expandable container 702 that is attached to the second volume 104b is used as the vapor control device (202, 602, 604, 702). In such embodiments, the method 1000 further includes allowing the vapor 110 and air to escape from the second volume 104b into the expandable container 702. In other embodiments, a fan 604 is used as the vapor control device (202, 602, 604, 702). In such embodiments, the method 1000 further includes operating the fan 604 to cause air and the vapor 110 to circulate within the second volume 104b. In still-further embodiments, a space-filling device 202, which is a removable object, is used as the vapor control device (202, 602, 604, 702). In such embodiments, the method 1000 further includes placing the space-filling device 202 within the second volume 104b to displace the vapor 110. The resulting displacement of the vapor 110 then increases a height of the vapor 110 to a second height 112b relative to a first height 112a that the vapor 110 has when the space-filling device 202 is removed from the second volume 104b.

Referring to all drawings and according to various embodiments of the present disclosure, a two-phase cooling system (200, 300, 400, 500, 600, 700, 800) is provided. According to some embodiments, the two-phase cooling system (200, 300, 400, 500, 600, 700, 800) includes an enclosure 102 having a first volume 104a and a second volume 104b, a heat source 106 located in the first volume 104a, and a liquid coolant 108 located in the first volume 104a such that the liquid coolant 108 is in contact with the heat source 106. The liquid coolant produces a vapor 110 partially filling the second volume 104b that is generated by the liquid coolant 108 when heat generated by the heat source 106 is absorbed by the liquid coolant 108. The two-phase cooling system (200, 300, 400, 500, 600, 700, 800) further includes a condenser 101 located in the second volume 104b that removes heat from the vapor 110, thereby condensing the vapor 110 into the condensed liquid coolant 108 that returns to the first volume 104a. The two-phase cooling system (200, 300, 400, 500, 600, 700, 800) further includes a space-filling device 202, located in the second volume 104b, which partially fills the second volume 104b and thereby displaces the vapor 110 from a portion of the second volume 104b.

In certain embodiments, the space-filling device 202 is a removable object. In such embodiments, the vapor 110 has a first height 112a when the space-filling device 202 is removed from the second volume 104b and has a second height 112b, which is greater than the first height 112a, when the space-filling device 202 is placed within the second volume 104b. For example, in certain embodiments the space-filling device 202 is an object that floats on the liquid coolant 108. In other embodiments, the space-filling device 202 is an object that is less dense than the vapor 110 and thereby floats in the vapor 110 above a surface of the liquid coolant 108.

In certain embodiments, the condenser 101 includes a conduit 116 through which a condenser coolant flows such that the condenser coolant absorbs heat from a portion of the vapor 110 that comes in contact with the conduit 116. Further, in such embodiments, the condenser 101 is located in a region of the second volume 104b that is adjacent to the space-filling device 202 along at least one edge of the space-filling device 202 such that the space-filling device 202 displaces the vapor 110 toward the condenser 101. In further embodiments, the conduit 116 is formed as a coil extending vertically to a third height 112c above a surface of the liquid coolant 108. In such embodiments, the third height 112c is greater than the first height 112a such that when the space-filling device 202 is placed within the second volume 104b the vapor 110 is displaced, thereby increasing a degree to which the vapor 110 comes in contact with the condenser 101. In still further embodiments, the conduit 116 is formed as a coil around a perimeter of a central region 114 of the second volume 104b such that the conduit 116 is adjacent to outer edges of the space-filling device 202 when the space-filling device 202 is placed within the second volume 104b.

In certain embodiments, the space-filling device 202 is a deformable object having a reconfigurable volume such that in a first configuration the space-filling device 202 has a first size and in a second configuration the space-filling device 202 has a second size that is different from the first size. For example, in certain embodiments, the space-filling device 202 is a bellows. In other embodiments, the space-filling device 202 is an inflatable bag 602 having an adjustable size that is increased or decreased by increasing or decreasing a volume of gas within the inflatable bag 602. In still-further embodiments, the space-filling device 202 includes a porous net 502 having a plurality of deformable objects 504 held within the porous net 502. In such embodiments, the porous net 502 includes an adjustable size such that the plurality of deformable objects 504 is compressed by the porous net 502 in a first configuration and the plurality of deformable objects 504 are expanded in a second configuration.

Disclosed embodiments provide cooling systems for computer system components having advantages over existing cooling systems. In this regard, two-phase cooling systems (200, 300, 400, 500, 600, 700, 800) are provided that include a liquid coolant 108 (i.e., a first phase) that absorbs heat from the computer system components 106 and thereby generates a vapor 110 (i.e., a second phase) that is cooled by a condenser 101 to thereby remove the heat. A vapor control device (202, 602, 604, 702) is provided, which alters a density distribution of the vapor 110 to increase a spatial overlap of the vapor 110 with the condenser 101, to thereby increase the efficiency of the heat-transfer coupling between the vapor 110 and the condenser 101. In various embodiments, the vapor control device (202, 504, 602, 604, 702) takes the form of a space-filling device 202, a deformable object 504, an inflatable bag 602, a fan 604, and an expandable container 702. Each of the embodiment vapor control devices (202, 602, 604, 702) displaces the vapor 110 toward the condenser 101, thereby improving heat transfer between the vapor 110 and the condenser 101, which leads to a corresponding improvement in overall cooling system performance.

An embodiment of a system (e.g., a two-phase cooling system) includes an enclosure having a first volume and a second volume, a heat source located in the first volume, and a liquid coolant located in the first volume such that the liquid coolant is in contact with the heat source. A vapor partially filling the second volume is generated by the liquid coolant when heat generated by the heat source is absorbed by the liquid coolant. A condenser located in the second volume removes heat from the vapor, thereby condensing the vapor into a condensed liquid coolant that returns to the first volume. A space-filling device, located in the second volume, partially fills the second volume, and thereby displaces the vapor from a portion of the second volume.

In various embodiments, the system is configured such that the space-filling device is a removable object that is configured to decrease a height of the vapor in the second volume to a first height when the space-filling device is removed from the second volume and is configured to increase the height of the vapor in the second volume to a second height when the space-filling device is placed within the second volume. In certain embodiments, the space-filling device is an object that is configured to float on the liquid coolant and in other embodiments, the space-filling device is an object that is configured to float in the vapor above a surface of the liquid coolant.

In some embodiments, the condenser includes a conduit configured to allow a condenser coolant to flow through such that the condenser coolant absorbs heat from a portion of the vapor that comes in contact with the conduit. The condenser is located in a region of the second volume that is adjacent to the space-filling device along at least one edge of the space-filling device such that the space-filling device displaces the vapor toward the condenser. In certain embodiments, the conduit is formed as a coil configured to extend vertically to a third height above a surface of the liquid coolant, such that the third height is greater than the first height. As such, when the space-filling device is placed within the second volume the vapor is displaced, thereby increasing a degree to which the vapor comes in contact with the condenser. In other embodiments, the conduit is formed as a coil around a perimeter of a central region of the second volume such that the conduit is adjacent to outer edges of the space-filling device when the space-filling device is placed within the second volume.

In various embodiments, the space-filling device is a deformable object having a reconfigurable volume such that in a first configuration the space-filling device has a first size and in a second configuration the space-filling device has a second size that is different from the first size. In certain embodiments, the space-filling device includes a bellows, and in other embodiments, the space-filling device is an inflatable bag including an adjustable size that is increased or decreased by increasing or decreasing a volume of gas within the inflatable bag. In other embodiments, the space-filling device includes a porous net including a plurality of deformable objects held within the porous net. In such embodiments, the porous net has an adjustable size such that the plurality of deformable objects is compressed by the porous net in a first configuration and the plurality of deformable objects are expanded in a second configuration.

An embodiment of a method (e.g., a method of cooling a heat source) includes enclosing a heat source within a first volume of an enclosure that comprises the first volume and a second volume, placing a liquid coolant within the first volume such that the liquid coolant is in contact with the heat source and such that the liquid coolant receives heat from the heat source and thereby generates a vapor, cooling the vapor with a condenser, which is located within the second volume, to thereby generate condensed liquid coolant that returns to the first volume, and controlling, with a space-filling device, a density distribution of the vapor. In certain embodiments, the space-filling device is a removable object, and the method further includes placing the space-filling device within the second volume such that the space-filling device displaces the vapor thereby causing the vapor to have a second height that is greater than a first height that the vapor includes when the space-filling device is removed from the second volume. In some embodiments, the removable object is configured to float on the liquid coolant, and the method further includes placing the removable object on a surface of the liquid coolant such that the removable object floats on the liquid coolant.

In other embodiments, the space-filling device is a deformable object having a reconfigurable volume, and the method further includes increasing a volume of the space-filling device from a first configuration having a first size to a second configuration having a second size that is larger than the first size such that the deformable object causes the vapor to have a second height that is greater than a first height that the vapor includes when the deformable object has the first size. In some embodiments, the deformable object is an inflatable bag, and the method further includes increasing a volume of gas within the inflatable bag to thereby increase the volume from the first size to the second size.

A further method (e.g., method of cooling a computing device) includes enclosing a computing device, which generates heat, within a first volume of an enclosure that has a first volume and a second volume. The method further includes placing a liquid coolant within the first volume such that the liquid coolant is in contact with the computing device and such that the liquid coolant receives heat from the computing device and thereby generates a vapor. The method further includes cooling the vapor with a condenser, which is located within the second volume, to thereby generate condensed liquid coolant that returns to the first volume. The method further includes controlling, with a vapor control device, a density distribution of the vapor. In some embodiments, the vapor control device is an expandable container attached to the second volume, and the method further includes allowing the vapor and air to escape from the second volume into the expandable container. In other embodiments, the vapor control device is a fan, and the method further includes operating the fan to cause air and the vapor to circulate within the second volume. In still-further embodiments, the vapor control device is a space-filling device that is a removable object, and the method further includes placing the space-filling device within the second volume to displace the vapor to thereby increase a height of the vapor to a second height relative to a first height that the vapor includes when the space-filling device is removed from the second volume.

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of the present disclosure.

What is claimed is:

1. A system, comprising:
an enclosure comprising a first volume and a second volume;
a heat source located in the first volume,
wherein the first volume is configured to contain a liquid coolant such that the liquid coolant is in contact with the heat source, and
the second volume is configured to contain a vapor partially filling the second volume that is generated by the liquid coolant when heat generated by the heat source is absorbed by the liquid coolant;
a condenser located in the second volume configured to remove heat from the vapor so that the vapor condenses into a liquid that returns to the first volume; and
a space-filling device, located in the second volume, which partially fills the second volume and is configured to displace the vapor from a portion of the second volume.

2. The system of claim 1, wherein:
the space-filling device is a removable object,
the space-filling device is configured to decrease a height of the vapor in the second volume to a first height when the space-filling device is removed from the second volume and is configured to increase the height of the vapor in the second volume to a second height when the space-filling device is placed within the second volume.

3. The system of claim 2, wherein the space-filling device comprises an object that is configured to float on the liquid coolant.

4. The system of claim 2, wherein the space-filling device comprises an object that is configured to float in the vapor above a surface of the liquid coolant.

5. The system of claim 2, wherein the condenser comprises a conduit configured to allow a condenser coolant to flow through such that the condenser coolant absorbs heat from a portion of the vapor that comes in contact with the conduit, and
wherein the condenser is located in a region of the second volume that is adjacent to the space-filling device along at least one edge of the space-filling device such that the space-filling device displaces the vapor toward the condenser.

6. The system of claim 5, wherein the conduit is formed as a coil configured to extend vertically to a third height above a surface of the liquid coolant, and
wherein the third height is greater than the first height such that when the space-filling device is placed within the second volume the vapor is displaced, thereby increasing a degree to which the vapor comes in contact with the condenser.

7. The system of claim 6, wherein the conduit is formed as a coil around a perimeter of a central region of the second volume such that the conduit is adjacent to outer edges of the space-filling device when the space-filling device is placed within the second volume.

8. The system of claim 1, wherein the space-filling device is a deformable object having a reconfigurable volume such that in a first configuration the space-filling device has a first size and in a second configuration the space-filling device has a second size that is different from the first size.

9. The system of claim 8, wherein the space-filling device comprises a bellows.

10. The system of claim 8, wherein the space-filling device comprises an inflatable bag comprising an adjustable size that is increased or decreased by increasing or decreasing a volume of gas within the inflatable bag.

11. The system of claim 8, wherein the space-filling device comprises a porous net comprising a plurality of deformable objects held within the porous net, and
wherein the porous net comprises an adjustable size such that the plurality of deformable objects is compressed by the porous net in a first configuration and the plurality of deformable objects are expanded in a second configuration.

12. A method, comprising:
enclosing a heat source within a first volume of an enclosure that comprises the first volume and a second volume;
placing a liquid coolant within the first volume such that the liquid coolant is in contact with the heat source and such that the liquid coolant receives heat from the heat source and thereby generates a vapor;
cooling the vapor with a condenser, which is located within the second volume, to thereby generate condensed liquid coolant that returns to the first volume; and
controlling, with a space-filling device, a density distribution of the vapor.

13. The method of claim 12, wherein the space-filling device is a removable object, the method further comprising:
placing the space-filling device within the second volume such that the space-filling device displaces the vapor thereby causing the vapor to have a second height that is greater than a first height that the vapor comprises when the space-filling device is removed from the second volume.

14. The method of claim 13, wherein the removable object is configured to float on the liquid coolant, the method comprising:
placing the removable object on a surface of the liquid coolant such that the removable object floats on the liquid coolant.

15. The method of claim 12, wherein the space-filling device is a deformable object having a reconfigurable volume, the method further comprising:
increasing a volume of the space-filling device from a first configuration having a first size to a second configuration having a second size that is larger than the first size such that the deformable object causes the vapor to have a second height that is greater than a first height that the vapor comprises when the deformable object has the first size.

16. The method of claim 15, wherein the deformable object is an inflatable bag, the method further comprising:
increasing a volume of gas within the inflatable bag to thereby increase the volume from the first size to the second size.

17. A method, comprising:
enclosing a computing device, which generates heat, within a first volume of an enclosure that comprises the first volume and a second volume;
placing a liquid coolant within the first volume such that the liquid coolant is in contact with the computing device and such that the liquid coolant receives heat from the computing device and thereby generates a vapor;
cooling the vapor with a condenser, which is located within the second volume, to thereby generate condensed liquid coolant that returns to the first volume; and
controlling, with a vapor control device, a density distribution of the vapor.

18. The method of claim 17, wherein the vapor control device is an expandable container attached to the second volume, the method further comprising:
allowing the vapor and air to escape from the second volume into the expandable container.

19. The method of claim 17, wherein the vapor control device is a fan, the method further comprising:
operating the fan to cause air and the vapor to circulate within the second volume.

20. The method of claim 17, wherein the vapor control device is a space-filling device that is a removable object, the method further comprising:
placing the space-filling device within the second volume to displace the vapor to thereby increase a height of the vapor to a second height relative to a first height that the vapor comprises when the space-filling device is removed from the second volume.
